(19) United States
(12) Patent Application Publication
(10) Pub. No.: US 2020/0234929 A1
(43) Pub. Date: Jul. 23, 2020

(54) PLASMA PROCESSING APPARATUS AND METHOD FOR MEASURING MISALIGNMENT OF RING MEMBER

(71) Applicant: TOKYO ELECTRON LIMITED, Tokyo (JP)

(72) Inventor: Atsushi OGATA, Miyagi (JP)

(73) Assignee: TOKYO ELECTRON LIMITED, Tokyo (JP)

(21) Appl. No.: 16/744,982

(22) Filed: Jan. 16, 2020

(30) Foreign Application Priority Data
Jan. 17, 2019 (JP) 2019-006034

(51) Int. Cl. H01J 37/32; G01B 21/24

(52) U.S. Cl. CPC H01J 37/32642; H01J 37/32715; H01J 2237/2007; H01J 2237/1502; H01J 2237/334; G01B 21/24

(57) ABSTRACT

A mounting table has a first surface for mounting jigs one by one and a second surface for mounting a ring member. An acquisition unit acquires a gap dimension between the second surface and a facing portion of the mounted jig. A measurement unit measures a lifted distance of the ring member at each of circumferential multiple locations when an upper surface of the ring member is in contact with the facing portion. A thickness calculation unit calculates, for each of the multiple locations, thickness at each of different radial positions of the ring member based on the gap dimension and the lifted distance. A misalignment calculation unit specifies a characteristic position of the ring member for each of the multiple locations based on the calculated thickness and calculate a misalignment amount between a center of a circle passing through the characteristic positions and a center of the first surface.

### CROSS-REFERENCE TO RELATED APPLICATIONS

This application claims priority to Japanese Patent Application No. 2019-006034, filed on Jan. 17, 2019, the entire contents of which are incorporated herein by reference.

### TECHNICAL FIELD

The present disclosure relates to a plasma processing apparatus and a method for measuring a misalignment of a ring member.

### BACKGROUND

Conventionally, there is known a plasma processing apparatus for performing plasma processing such as etching or the like on a target object such as a semiconductor wafer (hereinafter, also referred to as “wafer”) or the like using plasma. In the plasma processing apparatus, parts in the chamber are consumed by the plasma processing. For example, a ring member such as a focus ring that is disposed to surround an outer peripheral portion of a wafer to make the plasma uniform is quickly consumed because it is positioned close to the plasma. The degree of consumption of the ring member greatly affects processing results on the wafer. For example, if a height of a plasma sheath above the ring member and a height of a plasma sheath above the wafer are not the same, etching characteristics near the outer peripheral portion of the wafer deteriorate, thereby affecting the uniformity or the like.

Therefore, in the plasma processing apparatus, when the ring member is consumed to a certain extent, the consumed ring member is exchanged. Further, a technique for lifting the ring member using a driving mechanism in response to the consumption amount of the ring member to maintain a height of the wafer and a height of the ring member at a constant level has been proposed (see, e.g., Japanese Patent Application Publication Nos. 2002-176030 and 2016-146472).

In view of the above, the present disclosure provides a technique capable of properly measuring a misalignment of a ring member due to consumption.

### SUMMARY

In accordance with an aspect of the present invention, there is provided a plasma processing apparatus including: a mounting table having a first mounting surface on which a plurality of jigs are mounted sequentially one by one and a second mounting surface on which a ring member disposed to surround a target object is mounted, the jigs being used for measuring a shape of the ring member and respectively having facing portions facing an upper surface of the ring member, wherein respective positions of the facing portions of the jigs in a radial direction of the ring member are different from one another; one or more elevating mechanisms disposed at multiple locations in a circumferential direction of the ring member and configured to lift or lower the ring member with respect to the second mounting surface; an acquisition unit configured to acquire, when each of the jigs is mounted on the mounting surface, gap information indicating a gap dimension between the second mounting surface and the facing portion of the corresponding jig mounted on the first mounting surface; a measurement unit configured to measure a lifted distance of the ring member from the second mounting surface at each of the multiple locations in the circumferential direction of the ring member when the upper surface of the ring member is in contact with the facing portion of the corresponding jig by lifting the ring member using the elevating mechanisms in a state where the corresponding jig is mounted on the first mounting surface; a thickness calculation unit configured to calculate, for each of the multiple locations in the circumferential direction of the ring member, a thickness of the ring member at each of different radial positions of the ring member that correspond to the positions of the facing portions of the jigs based on the gap dimension indicated by the acquired gap information and the measured lifted distance of the ring member; and a misalignment calculation unit configured to specify a characteristic position that is used to characterize the shape of the ring member for each of the multiple locations in the circumferential direction of the ring member based on the calculated thickness of the ring member and calculate a misalignment amount between a center of a circle passing through the characteristic positions and a center of the first mounting surface.

### BRIEF DESCRIPTION OF THE DRAWINGS

The objects and features of the present disclosure will become apparent from the following description of embodiments, given in conjunction with the accompanying drawings, in which:

FIG. 1 is a schematic cross-sectional view showing a configuration of a plasma processing apparatus according to a first embodiment;

FIG. 2 is a schematic cross-sectional view showing a main configuration of a mounting table according to the first embodiment;

FIG. 3 is a block diagram showing a schematic configuration of a controller for controlling the plasma processing apparatus according to the first embodiment;

FIGS. 4 to 7 show exemplary shapes of a consumed focus ring;

FIG. 8 schematically shows an example of misalignment of a characteristic position of a focus ring;

FIGS. 9A and 9B show an example of a flow of a focus ring shape measurement process;

FIG. 10 shows an example of calculation of a misalignment amount;

FIG. 11 is a flowchart showing an example of a flow of a misalignment correction process according to the first embodiment; and

FIGS. 12A and 12B explain another example of a flow of a focus ring misalignment measurement process.

### DETAILED DESCRIPTION

Hereinafter, embodiments will be described in detail with reference to the accompanying drawings. Like reference numerals will be given to like or corresponding parts throughout the drawings.

Conventionally, there is known a plasma processing apparatus for performing plasma processing such as etching or the like on a target object such as a semiconductor wafer (hereinafter, also referred to as “wafer”) or the like using plasma. In the plasma processing apparatus, parts in the chamber are consumed by the plasma processing. For example, a ring member such as a focus ring that is disposed to surround an outer peripheral portion of a wafer to make the plasma uniform is quickly consumed because it is positioned close to the plasma. The degree of consumption of the ring member greatly affects processing results on the wafer. For example, if a height of a plasma sheath above the ring member and a height of a plasma sheath above the wafer are not the same, etching characteristics near the outer peripheral portion of the wafer deteriorate, thereby affecting the uniformity or the like.

Therefore, in the plasma processing apparatus, when the ring member is consumed to a certain extent, the consumed ring member is exchanged. Further, a technique for lifting the ring member using a driving mechanism in response to the consumption amount of the ring member to maintain a height of the wafer and a height of the ring member at a constant level has been proposed.

In the plasma processing apparatus, as the ring member is consumed, the shape of the ring member varies in a circumferential direction of the ring member. Therefore, a characteristic position that is used to characterize the shape of the ring member for each of multiple locations in the circumferential direction of the ring member may be positioned away from a concentric circle about a center of a mounting surface for mounting thereon a wafer. The characteristic position of the ring member may be, e.g., a radial position of the ring member where the thickness of the ring member is the maximum, or the like.

When the characteristic position is positioned away from the concentric circle about the center of the wafer mounting surface due to the consumption of the ring member, the center of the circle passing through the characteristic position is positioned away from the center of the wafer mounting surface. Such a misalignment (positional displacement) of the ring member due to the consumption deteriorates the uniformity of the plasma processing on the wafer in the circumferential direction. Therefore, in the plasma processing apparatus, there is a demand to properly measure the misalignment of the ring member due to the consumption.

### First Embodiment

<Configuration of Plasma Processing Apparatus>

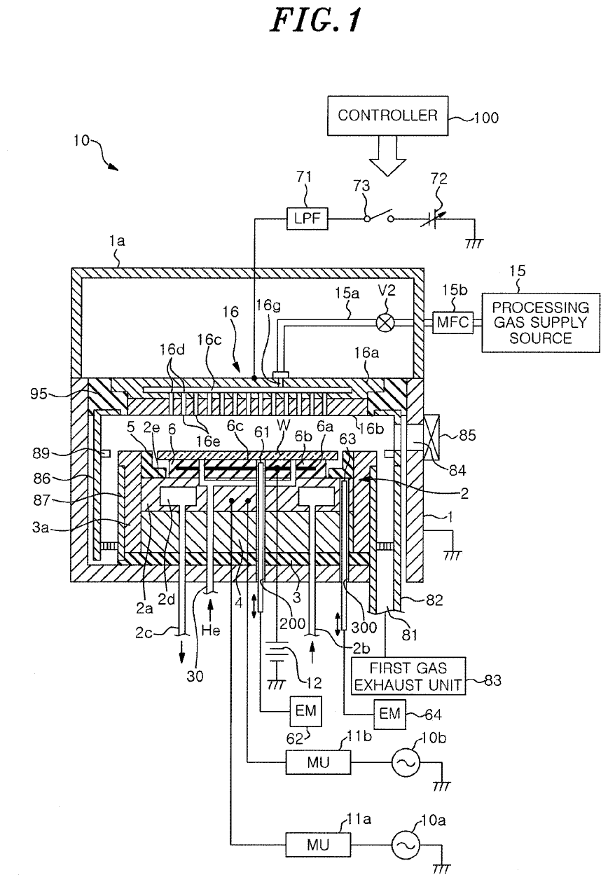

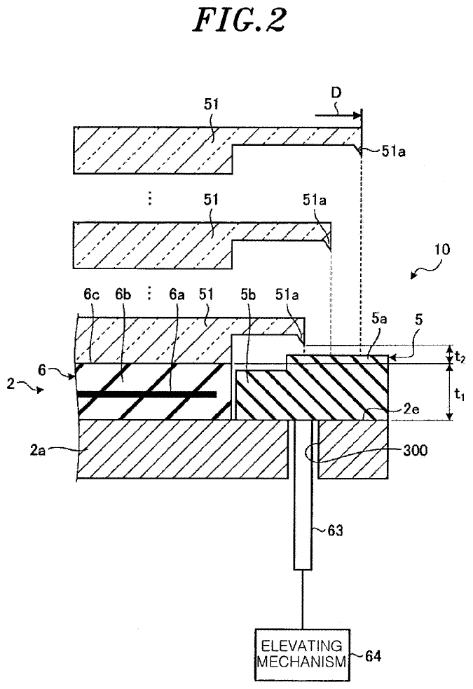

FIG. 1 is a schematic cross-sectional view showing a configuration of a plasma processing apparatus 10 according to a first embodiment. The plasma processing apparatus 10 includes an airtight processing chamber 1 that is electrically grounded. The processing chamber 1 has a cylindrical shape and is made of, e.g., aluminum or the like. The processing chamber 1 defines a processing space where plasma is generated. A mounting table 2 for horizontally supporting a semiconductor wafer (hereinafter, simply referred to as “wafer”) W that is a work-piece is disposed in the processing chamber 1. On the mounting table 2, the wafer W is mounted, and also a plurality of jigs 51 (see FIG. 2) used for measuring a shape of a focus ring 5 disposed to surround the wafer W are mounted sequentially one by one. The structure of the jigs 51 will be described later. The mounting table 2 includes a base 2a and an electrostatic chuck (ESC) 6.

The base 2a is made of a conductive metal, e.g., aluminum or the like, and serves as a lower electrode. The base 2a is supported by a support 4. The support 4 is supported by a support member 3 made of, e.g., quartz or the like. An annular focus ring 5 made of, e.g., single crystalline silicon, is disposed on an outer peripheral portion of the mounting table 2. An upper surface of an outer peripheral portion of the base 2a serves as a mounting surface 2e on which the focus ring 5 is mounted. A cylindrical inner wall member 3a made of, e.g., quartz or the like, is disposed in the processing chamber 1 to surround the peripheral portions of the mounting table 2 and the support 4.

A first RF power supply 10a is connected to the base 2a via a first matching unit (MU) 11a, and a second RF power supply 10b is connected to the base 2a via a second matching unit (MU) 11b. The first RF power supply 10a is configured to supply a high frequency power for plasma generation, which has a given frequency, to the base 2a of the mounting table 2. The second RF power supply 10b is configured to supply a high frequency power for ion attraction (for bias), which has a frequency lower than that of the first RF power supply 10a, to the base 2a of the mounting table 2. In this manner, a voltage can be applied to the mounting table 2. A shower head 16 serving as an upper electrode is disposed above the mounting table 2 to be opposite to the mounting table 2 in parallel therewith. The shower head 16 and the mounting table 2 function as a pair of electrodes (the upper electrode and the lower electrode).

The electrostatic chuck 6 is formed in a disk shape with a flat upper surface serving as a mounting surface 6c on which each of the jigs 51 or the wafer W is mounted. The electrostatic chuck 6 is disposed at a central portion of the base 2a in top view. The electrostatic chuck 6 has a structure in which an electrode 6a is embedded in an insulator 6b. A DC power supply 12 is connected to the electrode 6a. When a DC voltage is applied from the DC power supply 12 to the electrode 6a, each of the jigs 51 or the wafer W mounted on the mounting surface 6c is attracted and held by Coulomb force.

A coolant flow path 2d is formed inside the mounting table 2. A coolant inlet line 2b and a coolant outlet line 2c are connected to the coolant flow path 2d. The mounting table 2 can be controlled to a predetermined temperature by circulating a proper coolant, e.g., cooling water or the like, through the coolant flow path 2d. A gas supply line for supplying a cold heat transfer gas (backside gas) such as helium gas or the like to the backside of the wafer W is disposed to extend through the mounting table 2 and the like. The gas supply line 30 is connected to a gas supply source (not shown). With this configuration, the wafer W attracted and held by the electrostatic chuck 6 on the upper surface of the mounting table 2 can be controlled to a predetermined temperature.

A plurality of, e.g., three pin through-holes 200 (only one is shown in FIG. 1) is formed at a portion corresponding to the mounting surface 6c of the mounting table 2. Lifter pins 61 are disposed inside the pin through-holes 200, respectively. The lifter pins 61 are connected to an elevating mechanism(s) (EM) 62. The elevating mechanism(s) 62 lifts or lowers the lifter pins 61 so that the lifter pins 61 protrude beyond or retract below the mounting surface 6c of the mounting table 2. When the lifter pins 61 are lifted, the tip ends of the lifter pins 61 protrude beyond the mounting surface 6c of the mounting table 2, and the wafer W is held above the mounting surface 6c of the mounting table 2. On the other hand, when the lifter pins 61 are lowered, the tip ends of the lifter pins 61 are accommodated in the pin through-holes 200, and the wafer W is mounted on the mounting surface 6c of the mounting table 2. In this manner, the elevating mechanism(s) 62 lifts or lowers the wafer W with respect to the mounting surface 6c of the mounting table 2 using the lifter pins 61.

A plurality of, e.g., three pin through-holes (only one is shown in FIG. 1) 300 is disposed at a portion corresponding to the mounting surface 2e of the mounting table 2. Lifter pins 63 are disposed inside the pin through-holes 300, respectively. The lifter pins 63 are connected to an elevating mechanism(s) (EM) 64. The elevating mechanism(s) 64 lifts or lowers the lifter pins 63 so that the lifter pins 63 protrude beyond or retract below the mounting surface 2e of the mounting table 2. When the lifter pins 63 are lifted, the tip ends of the lifter pins 63 protrude beyond the mounting surface 2e of the mounting table 2, and the focus ring 5 is held above the mounting surface 2e of the mounting table 2. On the other hand, when the lifter pins 63 are lowered, the tip ends of the lifter pins 63 are accommodated in the pin through-holes 300, and the focus ring 5 is mounted on the mounting surface 2e of the mounting table 2. In this manner, the elevating mechanism(s) 64 lifts or lowers the focus ring 5 with respect to the mounting surface 2e of the mounting table 2 using the lifter pins 63.

The shower head 16 is disposed at a ceiling wall portion of the processing chamber 1. The shower head 16 includes a main body 16a and an upper ceiling plate 16b serving as an electrode plate. The shower head 16 is supported at an upper portion of the processing chamber 1 through an insulating member 95. The main body 16a is made of a conductive material, e.g., aluminum having an anodically oxidized surface. The main body 16a has a structure to detachably attach the upper ceiling plate 16b at a bottom portion of the main body 16a.

A gas diffusion space 16c is formed in the main body 16a. A plurality of gas holes 16d is formed at a bottom portion of the gas diffusion space 16c to be positioned under the gas diffusion space 16c. Gas injection holes 16e are formed through the upper ceiling plate 16b in a thickness direction of the upper ceiling plate 16b. The gas injection holes 16e communicate with the gas holes 16d, respectively. With this configuration, a processing gas supplied to the gas diffusion space 16c is diffused and supplied in a shower-like manner into the processing chamber 1 through the gas holes 16d and the gas injection holes 16e.

A gas inlet port 16g for introducing the processing gas into the gas diffusion space 16c is formed in the main body 16a. One end of a gas supply line 15a is connected to the gas inlet port 16g and the other end of the gas supply line 15a is connected to a processing gas supply source (gas supply unit) 15 for supplying a processing gas.

A mass flow controller (MFC) 15b and an opening/closing valve V2 are disposed in the gas supply line 15a in that order from an upstream side. The processing gas for plasma etching is supplied from the processing gas supply source 15 to the gas diffusion space 16c through the gas supply line 15a. The processing gas is diffused and supplied in a shower-like manner into the processing chamber 1 from the gas diffusion space 16c through the gas holes 16d and the gas injection holes 16e.

A variable DC power supply 72 is electrically connected to the shower head 16 serving as the upper electrode through a low pass filter (LPF) 71. The power supply of the variable DC power supply 72 can be on-off controlled by an on/off switch 73. A current and a voltage of the variable DC power supply 72 and on/off operation of the on/off switch 73 are controlled by a controller 100 to be described later. As will be described later, when plasma is generated in a processing space by applying the high frequency power from the first RF power supply 10a and the high frequency power from the second RF power supply 10b to the mounting table 2, the on/off switch 73 is turned on by the controller 100 and a predetermined DC voltage is applied to the shower head 16 serving as the upper electrode, if necessary.

A cylindrical grounding conductor 1a extends upward from a sidewall of the processing chamber 1 to be located at a position higher than the shower head 16. The cylindrical ground conductor 1a has a ceiling wall at the top thereof.

A gas exhaust port 81 is formed at a bottom of the processing chamber 1. A first gas exhaust unit 83 is connected to the gas exhaust port 81 through a gas exhaust line 82. The first gas exhaust unit 83 has a vacuum pump.

By operating the vacuum pump, a pressure in the processing chamber 1 can be decreased to a predetermined vacuum level. A loading/unloading port 84 for the wafer W is disposed at the sidewall of the processing chamber 1. A gate valve 85 for opening or closing the loading/unloading port 84 is disposed at the loading/unloading port 84.

A deposition shield 86 is disposed along an inner surface of the sidewall of the processing chamber 1. The deposition shield 86 prevents etching by-products (deposits) from being attached to the processing chamber 1. A conductive member (GND block) 89 is disposed at a portion of the deposition shield 86 at substantially the same height as the height of the wafer W. The conductive member 89 is connected to the ground such that a potential for the ground can be controlled. Due to the presence of the conductive member 89, abnormal discharge can be prevented. A deposition shield 87 extending along the inner wall member 3a is disposed in parallel with a lower portion of the deposition shield 86. The deposition shields 86 and 87 are detachably provided.

The operation of the plasma processing apparatus 10 configured as described above is integrally controlled by the controller 100. The controller 100 is, e.g., a computer, and controls the respective components of the plasma processing apparatus 10.

<Configuration of Mounting Table>

Next, the main configuration of the mounting table 2 according to the first embodiment will be described with reference to FIG. 2. FIG. 2 is a schematic cross-sectional view showing the main configuration of the mounting table 2 according to the first embodiment.

As shown in FIG. 2, the mounting table 2 includes the base 2a and the electrostatic chuck 6. The electrostatic chuck 6 has a disk shape and is disposed at the central portion of the base 2a to be coaxial with the base 2a. The electrostatic chuck 6 has a structure in which the electrode 6a is embedded in the insulator 6b. The upper surface of the electrostatic chuck 6 serves as the mounting surface 6c on which each of the jigs 51 or the wafer W is mounted. FIG. 2 shows a state where one jig 51 among the jigs 51 is mounted on the mounting surface 6c. The upper surface of the outer peripheral portion of the base 2a serves as the mounting surface 2e on which the focus ring 5 is mounted. The mounting surface 6c is an example of a first mounting surface, and the mounting surface 2e is an example of a second mounting surface.

The focus ring 5 is an annular member. The focus ring 5 is disposed to surround an outer peripheral portion of the base 2a to be coaxial with the base 2a. The focus ring 5 includes a body portion 5a and a protruding portion 5b projecting inward in a radial direction from an inner side surface of the body portion 5a. The upper surface of the protruding portion 5b is lower than the upper surface of the body portion 5a. In other words, the upper surface of the focus ring 5 has different heights depending on positions in the radial direction. For example, the height of the upper surface of the body portion 5a is higher than the height of the mounting surface 6c. The height of the upper surface of the protrusion 5b is lower than the height of the mounting surface 6c. The focus ring 5 is an example of a ring member.

The jigs 51 are used for measuring a shape of the focus ring 5. The jigs 51 are mounted sequentially one by one on the mounting surface 6c. Each of the jigs 51 has a facing portion 51a facing the upper surface of the focus ring 5. The respective positions of the facing portions 51a of the jigs 51 in the radial direction of the focus ring 5 are different from one another. In other words, distances D from the central axis of the focus ring 5 to the respective facing portions 51a of the jigs 51 in the radial direction of the focus ring 5 when the jigs 51 are sequentially (one by one) mounted are different from one another. Hereinafter, the position of the facing portion 51a corresponding to each distance D is appropriately referred to as “position D of the facing portion 51a.” The individual jigs 51, when mounted sequentially one by one on the mounting surface 6c, face the upper surface of the focus ring 5 at different locations in the radial direction of the focus ring 5 which correspond to the respective positions D of the facing portions 51a. Accordingly, when the elevating mechanism(s) lifts the focus ring 5 with respect to the mounting surface 2e of the mounting table 2 by using the lifter pins 63, the upper surface of the focus ring 5 is brought into contact with the facing portion 51a of the jig 51 mounted on the mounting surface 6c for each of the different locations in the radial direction of the focus ring 5.

Since each of the jigs 51 is attracted and held on the electrostatic chuck 6 by the Coulomb force, each jig 51 is made of a conductive material. Alternatively, each jig 51 may have a conductor layer on a surface to be in contact with the mounting surface 6c of the electrostatic chuck 6. The strength of each jig 51 is set such that the facing portion 51a is not deformed when the upper surface of the body portion 5a is in contact with the facing portion 51a of the jig 51.

The pin through-holes 300 for accommodating the lifter pins 63 are formed through the mounting surface 2e. The lifter pins 63 are connected to the elevating mechanism(s) 64. The elevating mechanism(s) 64 incorporates a driving motor, and extends or contracts an extensible and contractible rod by a driving force of the driving motor so that the lifter pins 63 can protrude beyond or retract below the mounting surface 2e. The elevating mechanism(s) 64 adjusts the height of the stop position of the lifter pins 63 such that the tip ends of the lifter pins 63 are in contact with the bottom surface of the focus ring 5 when the lifter pins 63 are accommodated in the pin through-holes 300. The elevating mechanism(s) 64 includes a torque sensor for detecting a driving torque generated at the driving motor at the time of raising the lifter pins 63. Data of the driving torque detected by the torque sensor is outputted to the controller 100 to be described later. The elevating mechanism(s) 64 includes a position detector, e.g., an encoder or the like, for detecting the positions of the tip ends of the lifter pins 63. The data of the positions of the tip ends of the lifter pins 63 detected by the position detector is outputted to the controller 100 to be described later.

In the above description, the case in which the tip ends of the lifter pins 63 are in contact with the bottom surface of the focus ring 5 when the lifter pins 63 are accommodated in the pin through-holes 300 has been described as an example. However, the present disclosure is not limited thereto. For example, the tip ends of the lifer pins 63 may not be in contact with the bottom surface of the focus ring 5 and there is a gap between the tip ends of the lifer pins 63 and the bottom surface of the focus ring 5 when the lifter pins 63 are accommodated in the pin through-holes 300. In this case, by using the position detector, e.g., an encoder or the like, for detecting the positions of the tip ends of the lifter pins 63, the positions where the tip ends of the lifter pins 63 are in contact with the bottom surface of the focus ring 5 is used as a reference point to adjust the positions of the tip ends of the lifter pins 63.

The pin through-holes 300, the lifter pins 63, and the elevating mechanism(s) 64 are arranged at multiple locations in a circumferential direction of the focus ring 5. In the plasma processing apparatus 10 according to the first embodiment, three sets of the pin through-holes 300, the lifter pins 63, and the elevating mechanisms 64 are disposed. For example, the sets each including the pin through-hole 300, the lifter pin 63, and the elevating mechanism 64 are arranged at the mounting table 2 at equal intervals in the circumferential direction of the mounting table 2. The torque sensor of each of the elevating mechanisms 64 detects the driving torque of the driving motor at the location where the corresponding elevating mechanism 64 is disposed and output the detection result to the controller 100. The position detector of each of the elevating mechanisms 64 detects the position of the tip end of the corresponding lifter pin 63 at the location where the corresponding elevating mechanism 64 is disposed, and output the detection result to the controller 100.

<Configuration of Controller>

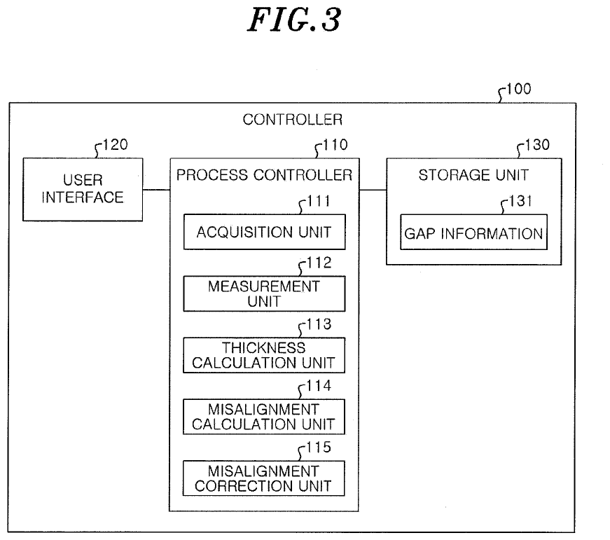

Next, the controller 100 will be described in detail. FIG. 3 is a block diagram showing a schematic configuration of the controller 100 for controlling the plasma processing apparatus 10 according to the first embodiment. The controller 100 includes a process controller 110, a user interface 120, and a storage unit 130.

The process controller 110 includes a central processing unit (CPU) and controls the respective components of the plasma processing apparatus 10.

The user interface 120 includes a keyboard through which a process manager inputs commands to operate the plasma processing apparatus 10, a display for visualizing an operation status of the plasma processing apparatus 10, and the like.

The storage unit 130 stores therein recipes including a control program (software), processing condition data and the like for realizing various processes performed by the plasma processing apparatus 100 under the control of the process controller 110. For example, the storage unit 130 stores gap information 131. The recipes including the control program, the processing condition data and the like can be stored in a computer-readable storage medium (e.g., a hard disk, an optical disk such as DVD or the like, a flexible disk, a semiconductor memory, or the like) or can be transmitted, when needed, from another apparatus through, e.g., a dedicated line, and used online.

The gap information 131 is data in which “gap dimension” between the mounting surface 2e and the facing portion 51a of the jig 51 mounted on the mounting surface 6c is stored when each jig 51 is mounted on the mounting surface 6c. The gap dimension is determined in advance based on the distance between the mounting surface 2e and the mounting surface 6c and the distance between the mounting surface 6c and the facing portion 51a of each jig 51 mounted on the mounting surface 6c. For example, when one jig 51 among the jigs 51 shown in FIG. 2 is mounted on the mounting surface 6c, the distance between the mounting surface 2e and the mounting surface 6c is “t₁,” and the distance between the mounting surface 6c and the facing portion 51a of the jig 51 mounted on the mounting surface 6c is “t₂.” Therefore, “t₁+t₂”, i.e., the sum of the distance between the mounting surface 2e and the mounting surface 6c and the distance between the mounting surface 6c and the facing portion 51a of the jig 51 mounted on the mounting surface 6c, is determined in advance as the gap dimension. In this case, the gap dimension “t₁+t₂” is stored as the gap information 131 in the storage unit 130.

Referring back to FIG. 3, the process controller 110 has an internal memory for storing programs or data, and reads out a control program stored in the storage unit 130 and executes the read-out control program. The process controller 110 may serve as various processing units in response to the execution of the control program. For example, the process controller 110 includes an acquisition unit 111, a measurement unit 112, a thickness calculation unit 113, a misalignment calculation unit 114, and a misalignment correction unit 115.

In the plasma processing apparatus 10, when the plasma processing is performed, the focus ring 5 is consumed and the thickness of the focus ring 5 is reduced. When the thickness of the focus ring 5 is reduced, the height of the plasma sheath above the focus ring 5 is not the same as that of the plasma sheath above the wafer W, and etching characteristics are changed.

For example, when the height of the plasma sheath above the focus ring 5 is lower than the height of the plasma sheath above the wafer W, the plasma sheath is sloped near the peripheral portion of the wafer W, and positive ions are incident on the peripheral portion of the wafer W at an inclined angle. The changes in the incident angle of the positive ions lead to changes in the etching characteristics. For example, shape abnormality in which a hole formed by etching extends obliquely with respect to a vertical direction of the wafer W occurs. Such a shape abnormality is referred to as “tilting.”

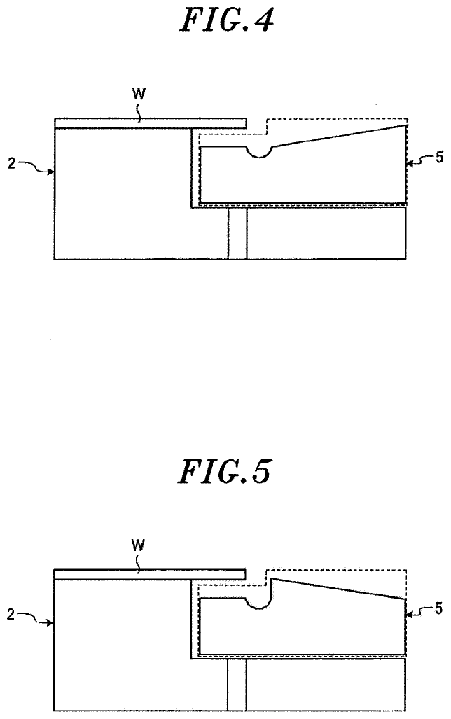

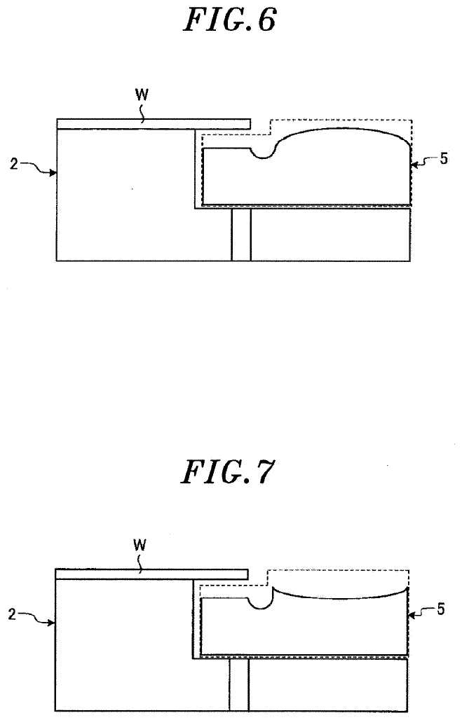

Meanwhile, the shape of the consumed focus ring 5 varies depending on the processing conditions of the plasma processing. For example, the consumed focus ring 5 may have any one of four shapes shown in FIGS. 4 to 7. FIGS. 4 to 7 show exemplary shapes of the consumed focus ring 5. FIG. 4 shows a shape in which a thickness of the focus ring 5 increases toward a radially outer side of the focus ring 5. FIG. 5 shows a shape in which a thickness of the focus ring 5 decreases toward the radially outer side of the focus ring 5. FIG. 6 shows a shape in which a thickness of the focus ring 5 becomes the maximum at the central portion of the focus ring 5 in the radial direction. FIG. 7 shows a shape in which a thickness of the focus ring 5 becomes the minimum at the central portion of the focus ring 5 in the radial direction.

Further, in the plasma processing apparatus 10, as the focus ring 5 is consumed, the shape varies in the circumferential direction of the focus ring 5. Therefore, the characteristic position that is used to characterize the shape of the focus ring 5 for each of multiple locations in the circumferential direction of the focus ring 5 is positioned away from a concentric circle about the center of the mounting surface 6c for mounting thereon the wafer W. The characteristic position of the focus ring 5 may be, e.g., a radial position of the focus ring 5 (hereinafter referred to as “peak position”) where the thickness of the focus ring 5 is the maximum, or the like.

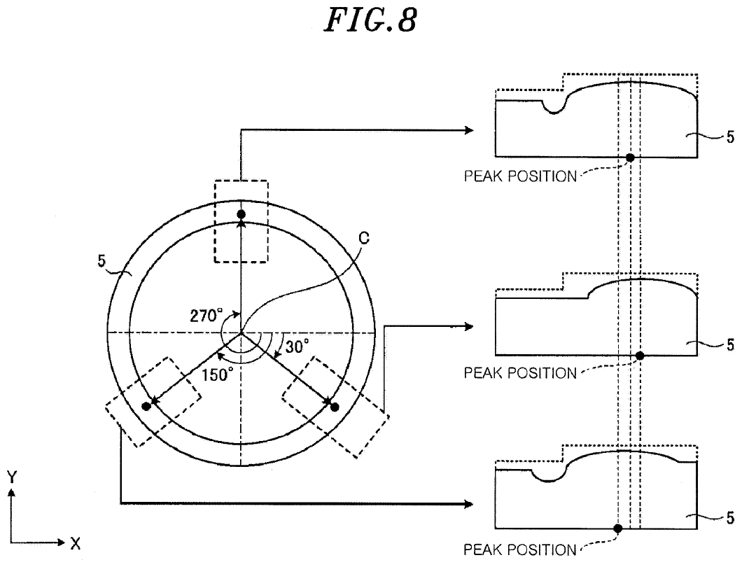

FIG. 8 schematically shows an example of the misalignment of the characteristic position of the focus ring 5. FIG. 8 shows three peak positions that are characteristic positions of the focus ring 5 for three positions in the circumferential direction of the focus ring 5. In the example of FIG. 8, the peak positions of the focus ring 5 for a 30° position, a 150° position, and a 270° position in the circumferential direction of the focus ring 5 are positioned away from the concentric circle centered on a center C of the mounting surface 6c.

When the characteristic positions (e.g., the peak positions) of the focus ring 5 are positioned away from the concentric circle centered on the center of the mounting surface 6c, a center of a circle passing through the characteristic positions is positioned away from the center C of the mounting surface 6c. Such a misalignment of the focus ring 5 deteriorates the characteristics or the uniformity of the plasma processing performed on the wafer W. Therefore, in the plasma processing apparatus 10, there is a demand to properly measure the misalignment of the focus ring 5 due to the consumption.

Accordingly, in the plasma processing apparatus 10, the shape of the focus ring 5 is measured using the jigs 51 that are mounted sequentially one by one on the mounting surface 6c, and the misalignment of the focus ring 5 due to the consumption is measured based on the measurement result.

Referring back to FIG. 3, the acquisition unit 111 acquires the gap information 131 indicating the gap dimension between the mounting surface 2e and the facing portion 51a of the jig 51 mounted on the mounting surface 6c when each jig 51 is mounted on the mounting surface 6c. For example, the acquisition unit 111 reads out and acquires the gap information 131 indicating the gap dimension between the mounting surface 2e and the facing portion 51a of each jig 51 mounted on the mounting surface 6c from the storage unit 130. In the present embodiment, the gap information 131 is stored in advance in the storage unit 130. However, when the gap information 131 is stored in another device, the acquisition unit 111 may acquire the gap information 131 from another device through a network.

Then, when each jig 51 is mounted on the mounting surface 6c, the lifter pins 63 are lifted by using the elevating mechanisms 64, respectively, in a state where each jig 51 is mounted on the mounting surface 6c to lift the focus ring 5 until the upper surface of the focus ring 5 becomes in contact with the facing portion 51a of each jig 51. Then, the measurement unit 112 measures a lifted distance of the focus ring 5 from the mounting surface 2e when the upper surface of the focus ring 5 is in contact with the facing portion 51a. For example, the focus ring 5 is lifted by using the elevating mechanisms 64 arranged at multiple locations in the circumferential direction of the focus ring 5. Then, the measuring unit 112 measures the lifted distance of the focus ring 5 from the mounting surface 2e at each of the multiple locations in the circumferential direction of the focus ring 5 when the upper surface of the focus ring 5 is in contact with the facing portion 51a. Whether or not the upper surface of the focus ring 5 is in contact with the facing portion 51a is determined by comparing a predetermined threshold with a value of the driving torque detected by the torque sensor of the corresponding elevating mechanism 64 at each of the multiple locations where the elevating mechanisms 64 are arranged. The lifted distance of the focus ring 5 from the mounting surface 2e at each of the multiple locations is measured by using the position of the tip end of the lifter pin 63 detected by the position detector of the corresponding elevating mechanism 64 at each of the multiple locations where the elevating mechanisms 64 are arranged.

The thickness calculation unit 113 calculates the thickness of the focus ring 5 at each of the different locations in the radial direction of the focus ring 5 based on the gap dimension indicated by the gap information 131 acquired by the acquisition unit 111 and the lifted distance of the focus ring 5 measured by the measurement unit 112. For example, when the gap dimension of one jig 51 shown in FIG. 2 indicated by the gap information 131 is “t₁+t₂,” the thickness calculation unit 113 calculates the thickness of the focus ring 5 by subtracting the measured lifted distance of the focus ring 5 from the gap dimension “t₂+t₂.” The thickness calculation unit 113 calculates the thickness of the focus ring 5 at each of the different locations in the radial direction of the focus ring 5 which respectively correspond to the positions of the facing portions 51a of the jigs 51. Further, the thickness calculation unit 113 calculates the thickness of the focus ring 5 at each of the different locations in the radial direction of the focus ring 5 for each of the multiple locations in the circumferential direction of the focus ring 5.

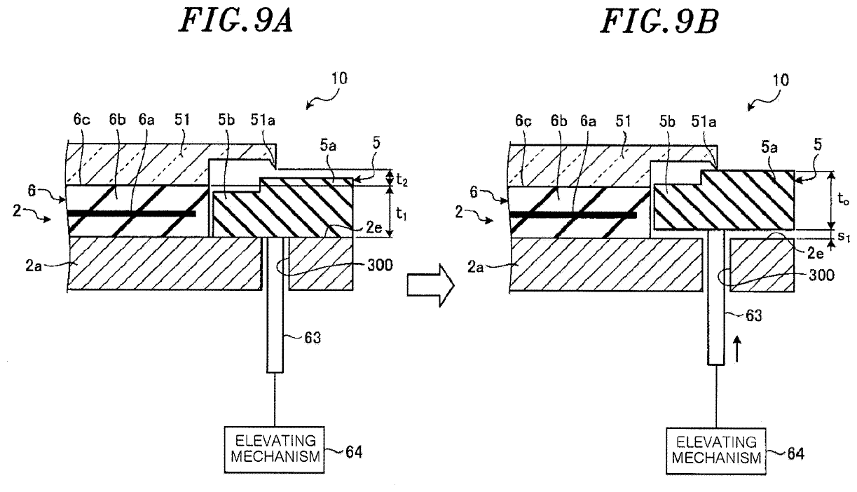

Next, a specific example of the measurement of the shape of the focus ring 5 will be described. FIGS. 9A and 9B show an example of the flow of the process of measuring the shape of the focus ring 5.

FIG. 9A shows a state where one jig 51 among the jigs 51 is mounted on the mounting surface 6c. The jig 51 has the facing portion 51a facing the upper surface of the focus ring 5. The distance between the mounting surface 2e and the mounting surface 6c is “t₁,” and the distance between the mounting surface 6c and the facing portion 51a of the jig 51 mounted on the mounting surface 6c is “t₂.” Therefore, “t₁+t₂” is the gap dimension between the mounting part 2e and the facing portion 51a of the jig 51 mounted in the mounting surface 6c. In the plasma processing apparatus 10, the focus ring 5 is lifted by lifting the lifter pins 63 using the elevating mechanisms 64 until the upper surface of the focus ring 5 becomes in contact with the facing portion 51a of the jig 51.

FIG. 9B shows a state where the upper surface of the body portion 5a is in contact with the facing portion 51a of the jig 51. In the example of FIG. 9B, the focus ring 5 is lifted from the mounting surface 2e by “s₁.” As shown in FIG. 9B, the measurement unit 112 calculates the lifted distance “s₁” of the focus ring 5 from the mounting surface 2e when the upper surface of the body portion 5a is in contact with the facing portion 51a of the jig 51. Then, in the plasma processing apparatus 10, the thickness calculation unit 113 calculates the thickness “tₒ” of the focus ring 5 by subtracting the measured lifted distance “s₁” of the focus ring 5 from the gap dimension “t₁+t₂.” The measurement of the lifted distance “s₁₁” by the measurement unit 112 and the calculation of the thickness “tₒ” of the focus ring 5 by the thickness calculation unit 113 are repeated for each of the jigs 51 sequentially (one by one) mounted on the mounting surface 6c. Accordingly, the plasma processing apparatus 10 can properly measure the shape of the focus ring 5 with a simple configuration in which the focus ring 5 is lifted until the upper surface of the focus ring 5 becomes in contact with the facing portion 51a of each of the jigs 51 sequentially (one by one) mounted on the mounting surface 6c.

Referring back to FIG. 3, the misalignment calculation unit 114 specifies the characteristic position of the focus ring 5 for each of the multiple locations in the circumferential direction of the focus ring 5 based on the thickness of the focus ring 5 calculated by the thickness calculation unit 113. The characteristic position of the focus ring 5 may be any position that can be used to characterize the shape of the focus ring 5. For example, the characteristic position is the peak position. The misalignment calculation unit 114 calculates the misalignment amount between the center of the circle passing through the characteristic positions of the focus ring 5 and the center of the mounting surface 6c.

Accordingly, in the plasma processing apparatus 10, the misalignment of the focus ring 5 due to the consumption can be properly measured with a simple configuration using the jigs 51 that are mounted sequentially one by one on the mounting surface 6c.

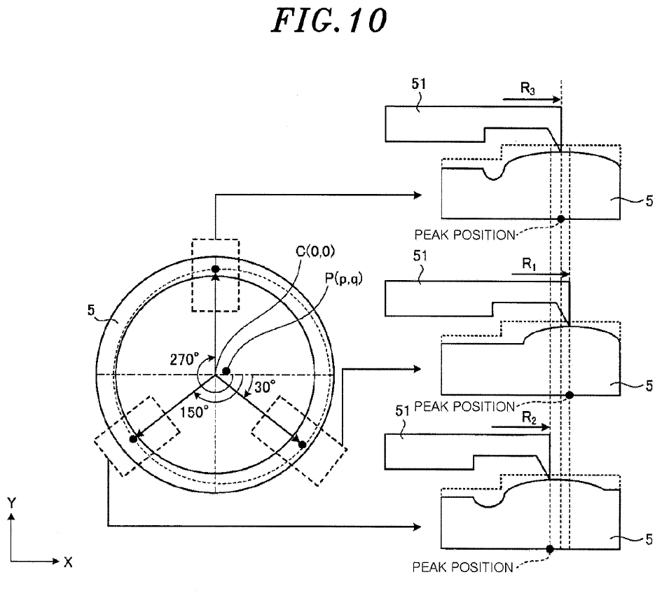

FIG. 10 shows an example of the misalignment calculation. FIG. 10 shows peak positions that are the characteristic positions of the focus ring 5 for each of a 30° position, a 150° position, and a 270° position in the circumferential direction of the focus ring 5. The focus ring 5 is disposed such that the center of the focus ring 5 and the center C of the mounting surface 6c coincide with each other. The misalignment calculation unit 114 specifies a radial position of the focus ring 5 where the thickness of the focus ring 5 calculated by the thickness calculation unit 113 is the maximum as the peak position for each of the 30° position, the 150° position, and the 270° position. The peak position positionally corresponds to the position D of the facing portion 51a of any one of the jigs 51. By specifying the peak position of the focus ring 5, the distance from the center C of the mounting surface 6c to the peak position of the focus ring 5 is specified for each of the 30° position, the 150° position, and the 270° position. In the example of FIG. 10, the distance from the center C of the mounting surface 6c to the peak position of the focus ring 5 for the 30° position is specified as R₁. The distance from the center C of the mounting surface 6c to the peak position of the focus ring 5 for the 150° position is specified as R₂. The distance from the center C1 of the mounting surface 6c to the peak position of the focus ring 5 for the 270° position is specified as R₃. Therefore, the peak position of the focus ring 5 at the 30° position is expressed as (R1·cos 30°, −R1·sin 30°) on the XY plane having the center C of the mounting surface 6c as the origin. Similarly, the peak position of the focus ring 5 at the 150° position is expressed as (−R2·cos 150°, −R2·sin 150°) on the XY plane having the center C of the mounting surface 6c as the origin. Further, the peak position of the focus ring 5 at the 270° position is expressed as (R3·cos 270°, R3·sin 270°) on the XY plane having the center C of the mounting surface 6c as the origin.

Then, the misalignment calculation unit 114 calculates a center P of the circle passing through the peak positions of the focus ring 5 at the 30° position, at the 150° position, and at the 270° position. On the XY plane having the center C of the mounting surface 6c as the origin, a circle having a center (p, q) and a radius of r is expressed by the following Eq. (1).

(X−p)²+(Y−q)²=r² Eq. (1)

The misalignment calculation unit 114 calculates the center P (p, q) of the circle passing through the three peak positions by substituting the coordinates of the three peak positions into Eq. (1). In other words, the misalignment calculation unit 114 calculates (p, q) as the misalignment amount between the center P of the circle passing through the three peak positions of the focus ring 5 and the center C of the mounting surface 6c.

Referring back to FIG. 3, the misalignment correction unit 115 corrects the position of the focus ring 5 based on the misalignment amount calculated by the misalignment calculation unit 114. For example, the misalignment correction unit 115 controls the transfer mechanism for transferring the focus ring 5 to correct the mounting position of the focus ring 5 on the mounting surface 2e by a correction amount corresponding to the misalignment amount calculated by the misalignment calculation unit 114. For example, when the misalignment amount calculated by the misalignment calculation unit 114 is (p, q), the misalignment correction unit 115 controls the transfer mechanism for transferring the focus ring 5 to correct the mounting position of the focus ring 5 on the mounting surface 2e by the correction amount (−p, −q).

Further, the misalignment correction unit 115 may individually control the elevating mechanisms 64 to correct the mounting position of the focus ring 5 on the mounting surface 2e by the correction amount corresponding to the misalignment amount calculated by the misalignment calculation unit 114. For example, the misalignment correction unit 115 individually controls the elevating mechanisms 64 to tilt the focus ring 5 and lift or lower the tilted focus ring 5 so that the focus ring 5 can be partially in contact with the mounting surface 2e. Then, the misalignment correction unit 115 uses the rotation of the focus ring 5 caused by the contact with the mounting surface 2e to correct the mounting position of the focus ring 5 on the mounting surface 2e by the correction amount corresponding to the misalignment amount calculated by the misalignment calculation unit 114. For example, when the misalignment amount calculated by the misalignment calculation unit 114 is (p, q), the misalignment correction unit 115 individually controls the elevating mechanisms 64 to correct the mounting position of the focus ring 5 on the mounting surface 2e by the correction amount (−p, −q).

<Flow of the Process>

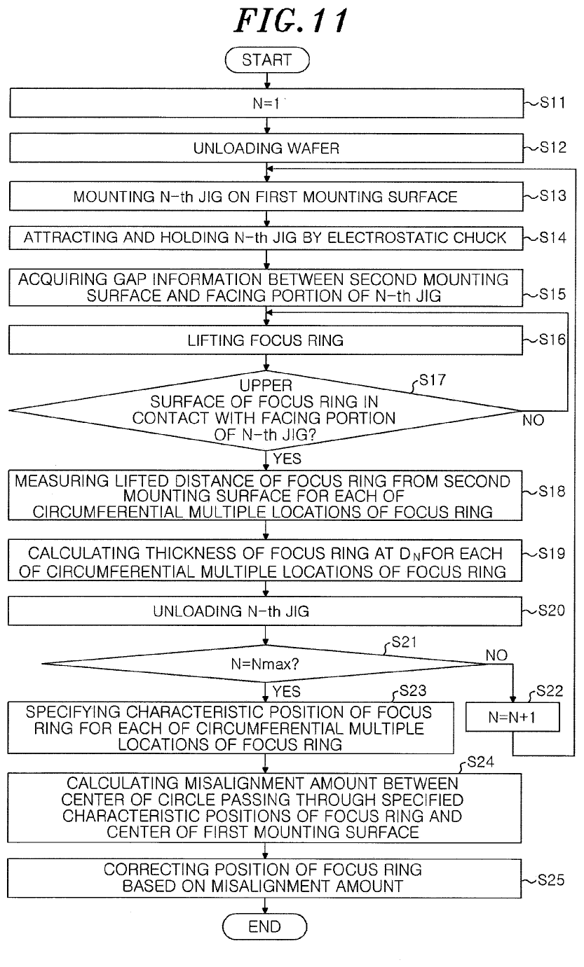

Next, a flow of a misalignment correction process in which the plasma processing apparatus 10 measures the misalignment of the focus ring 5 due to the consumption and corrects the position of the focus ring 5 based on the measurement result will be described. FIG. 11 is a flowchart showing an example of the flow of the misalignment correction process according to the first embodiment. This misalignment correction process is performed, e.g., after the plasma processing on the wafer W is completed.

As shown in FIG. 11, a variable N for counting the jigs 51 mounted sequentially one by one on the mounting surface 6c is initialized to “1” (step S11), and the wafer W is unloaded from the processing chamber 1 (step S12). Then, an N-th jig (i.e., the first jig) 51 is mounted on the mounting surface 6c (first mounting surface) (step S13). Next, the N-th jig 51 is attracted and held by the electrostatic chuck 6 (step S14). At this time, the electrostatic attractive force of the electrostatic chuck 6 is set to prevent the jig 51 from being separated from the mounting surface 6c when the facing portion 51a of the jig 51 and the upper surface of the focus ring 5 are brought into contact with each other.

The acquisition unit 111 acquires the gap information 131 indicating the gap dimension between the mounting surface (second mounting surface) 2e and the facing portion 51a of the N-th jig 51 mounted on the mounting surface 6c (step S15).

The focus ring 5 is lifted by lifting the lift pins 63 using the elevating mechanisms 64 in a state where the N-th jig 51 mounted on the mounting surface 6c is attracted and held by the electrostatic chuck 6 (step S16). The measurement unit 112 determines whether or not the upper surface of the focus ring 5 is in contact with the facing portion 51a of the N-th jig 51 (step S17). When the upper surface of the focus ring 5 is not in contact with the facing portion 51a of the N-th jig 51 (NO in step S17), the lifting of the focus ring 5 is continued (step S16).

On the other hand, when the upper surface of the focus ring 5 is in contact with the facing portion 51a of the N-th jig 51 (YES in step S17), the measurement unit 112 measures the lifted distance of the focus ring 5 from the mounting surface 2e (step S18).

The thickness calculation unit 113 calculates the thickness of the focus ring 5 at a radial position D_{N} for each of multiple locations in the circumferential direction of the focus ring 5 based on the gap dimension of the gap information 131 and the measured lifted distance of the focus ring 5 (step S19). The radial position D_{N} of the focus ring 5 corresponds to the position D of the facing portion 51a of the N-th jig 51.

Then, the N-th jig 51 is unloaded from the processing chamber 1 (step S20). The thickness calculation unit 113 determines whether or not the variable N has reached a specified number Nₘₐₓ (Nₘₐₓ≥3) (step S21). When the variable N has not reached the specified number Nₘₐₓ (NO in step S21), the thickness calculation unit 113 increases the value of the variable N by 1 (step S22) and returns to step S13. Accordingly, the thickness of the focus ring 5 is calculated at each of the different locations D_{N} (N=1, 2, . . . , Nₘₐₓ) in the radial direction of the focus ring 5.

On the other hand, when the variable N has reached the specified number Nₘₐₓ (YES in step S21), the thickness calculation unit 113 proceeds to step S23.

The misalignment calculation unit 114 specifies a characteristic position (e.g., a peak position) of the focus ring 5 for each of the multiple locations in the circumferential direction of the focus ring 5 based on the thickness of the focus ring 5 calculated by the thickness calculation unit 113 (step S23).

The misalignment calculation unit 114 calculates the misalignment amount between the center of the circle passing through the specified characteristic positions of the focus ring 5 and the center of the mounting surface 6c (step S24).

The misalignment correction unit 115 corrects the position of the focus ring 5 based on the misalignment amount calculated by the misalignment calculation unit 114 (step S25). Then, the processing is terminated.

As described above, the plasma processing apparatus 10 according to the first embodiment includes the mounting table 2, the elevating mechanisms 64, the acquisition unit 111, the thickness measurement unit 112, the thickness calculation unit 113, and the misalignment calculation unit 114. The mounting table 2 has the mounting surface 6c on which a plurality of jigs 51 are mounted sequentially one by one and the mounting surface 2e on which the focus ring 5 is mounted. The jigs 51 are used for measuring the shape of the focus ring 5 disposed to surround the wafer W. Each of the jigs 51 has the facing portion 51a facing the upper surface of the focus ring 5. The respective positions of the facing portions 51a of the jigs 51 in the radial direction of the focus ring 5 are different from one another. The elevating mechanisms 64 are arranged at multiple locations in the circumferential direction of the focus ring 5 and lift or lower the focus ring 5 with respect to the mounting surface 2e. The acquisition unit 111 acquires the gap information indicating the gap dimension between the mounting surface 2e and the facing portion 51a of each of the jigs 51 mounted on the mounting surface 6c. The focus ring 5 is lifted by using the elevating mechanisms 64 in a state where the corresponding jig 51 is mounted on the mounting surface 6c, and the measurement unit 112 measures a lifted distance of the focus ring 5 from the mounting surface 2e at each of the multiple locations in the circumferential direction of the focus ring 5 when the upper surface of the focus ring 5 is in contact with the facing portion 51a. The thickness measurement unit 112 calculates, for each of the multiple locations in the circumferential direction of the focus ring 5, the thickness of the focus ring 5 at each of different radial positions of the focus ring 5 based on the gap dimension indicated by the acquired gap information 131 and the measured lifted distance of the focus ring 5. The misalignment calculation unit 114 specifies the characteristic position that is used to characterize the shape of the focus ring 5 for each of the multiple locations in the circumferential direction of the focus ring 5 based on the calculated thickness of the focus ring 5. The misalignment calculation unit 114 calculates the misalignment amount between the center of the circle passing through the specified characteristic positions of the focus ring 5 and the center of the mounting surface 6c. Accordingly, the plasma processing apparatus 10 can properly measure the misalignment of the focus ring 5 due to the consumption with a simple configuration using the jigs 51 that are mounted sequentially one by one on the mounting surface 6.

The plasma processing apparatus 10 according to the first embodiment further includes the misalignment correction unit 115. The misalignment correction unit 115 corrects the position of the focus ring 5 based on the misalignment amount calculated by the misalignment calculation unit 114. Accordingly, the plasma processing apparatus 10 can align the characteristic positions that are used to characterize the shape of the focus ring 5 on a concentric circle about the center of the mounting surface 6c on which the wafer W is mounted, and can improve the uniformity of the plasma processing in the circumferential direction of the wafer W.

In the plasma processing apparatus 10 according to the first embodiment, the gap dimension is determined in advance based on the distance between the mounting surface 2e and the mounting surface 6c and the distance between the mounting surface 6c and the facing portion 51a of each of the jigs 51 that is mounted on the mounting surface 6c. Accordingly, the plasma processing apparatus 10 can highly accurately measure the shape of the focus ring 5 even when the mounting table 2 or each jig 51 has dimensional errors.

In the plasma processing apparatus 10 according to the first embodiment, the mounting table 2 includes the electrostatic chuck 6 for attracting and holding each of the jigs 51 that are mounted sequentially one by one on the mounting surface 6c. The focus ring 5 is lifted by using the elevating mechanism 64 in a state where the corresponding jig 51 mounted on the mounting surface 6c is attracted and held by the electrostatic chuck 6. Accordingly, the plasma processing apparatus 10 can prevent each of the jigs 51 from being separated from the mounting surface 6c when the upper surface of the focus ring 5 becomes in contact with the facing portion 51a of the corresponding jig 51, which makes it possible to highly accurately measure the shape of the focus ring 5.

Although various embodiments have been described above, the present disclosure can be variously modified without being limited to the above-described embodiments. For example, the above-described plasma processing apparatus 10 is a capacitively-coupled plasma processing apparatus 10. However, it is also possible to employ any plasma processing apparatus 10. For example, the plasma processing apparatus 10 may be any type of plasma processing apparatus 10 such as an inductively-coupled plasma processing apparatus 10 or a plasma processing apparatus 10 for exciting a gas by surface waves such as microwaves.

In the above-described embodiments, the case of measuring the misalignment of the focus ring 5 disposed to surround the wafer W has been described as an example. However, the present disclosure is not limited thereto. For example, when another ring member such as a cover ring or the like is disposed to surround the focus ring 5, the misalignment of another ring member may be measured in the same manner as that used in the process of measuring the misalignment of the focus ring 5 according to the above-described embodiments.

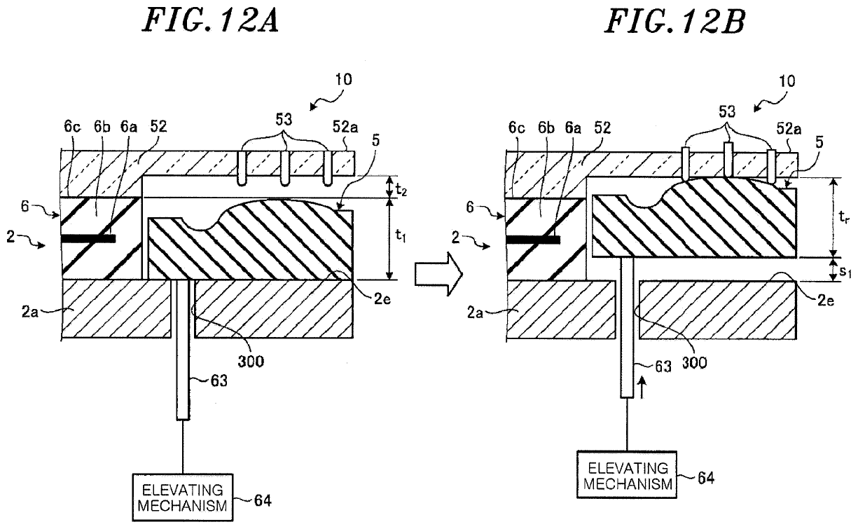

In the above-described embodiment, the case of measuring the misalignment of the focus ring 5 using the jigs 51 that are mounted sequentially one by one on the mounting surface 6c has been described as an example. However, the present disclosure is not limited thereto. FIGS. 12A and 12B show another example of the flow of the process of measuring the misalignment of the focus ring 5. For example, as shown in FIGS. 12A and 12B, the misalignment of the focus ring 5 may be measured using one jig 52 mounted on the mounting surface 6c. FIG. 12A shows a state in which the jig 52 is mounted on the mounting surface 6c. The jig 52 is used for measuring the shape of the focus ring 5. The jig 52 has a facing portion 52a facing the upper surface of the focus ring 5. A plurality of vertically movable probes 53 is disposed at the facing portion 52a along the radial direction of the focus ring 5.

The distance between the mounting surface 2e and the mounting surface 6c is “t₁,” and the distance between the mounting surface 6c and the facing portion 52a of the jig 52 mounted on the mounting surface 6c is “t₂.” Therefore, “t₁+t₂” is the gap dimension between the mounting surface 2e and the facing portion 52a of the jig 52 mounted on the mounting surface 6c. In the plasma processing apparatus 10, the acquisition unit 111 acquires, e.g., “t₁+t₂” that is the gap dimension between the mounting surface 2e and the facing portion 52a of the jig 52 mounted on the mounting surface 6c. In a state where the jig 52 is mounted on the mounting surface 6c, the lifter pins 63 are lifted by using the elevating mechanisms 64 to lift the focus ring 5, and the probes 53 are pushed upward by the focus ring 5 that is being lifted.

FIG. 12B shows a state where the upper surface of the focus ring 5 is in contact with the facing portion 52a of the jig 52. In the example of FIG. 12B, the focus ring 5 is lifted from the mounting surface 2e by a distance “s₁.” As shown in FIG. 12B, the measurement unit 112 calculates the lifted distance “s₁” of the focus ring 5 from the mounting surface 2e at each of the multiple locations in the circumferential direction of the focus ring 5 when the upper surface of the focus ring 5 is in contact with the facing portion 52a of the jig 52. The thickness calculation unit 113 calculates a reference thickness of the focus ring 5 for each of the multiple locations in the circumferential direction of the focus ring 5 based on the gap dimension “t₁+t₂” and the measured lifted distance “s₁” of the focus ring 5. The reference thickness is used for measuring a shape of the focus ring 5 and corresponds to a thickness of a thickest portion of the focus ring 5. In the example of FIG. 12B, the thickness calculation unit 113 calculates the reference thickness “tᵣ” used for measuring the shape of the focus ring 5 by subtracting the lifted distance “s₁” of the focus ring 5 from the gap dimension “t₁+t₂.”

After the reference thickness “tᵣ” is calculated by the thickness calculation unit 113, the jig 52 is restored and the shape of the focus ring 5 is measured based on the restored jig 52 and the calculated reference thickness “tᵣ.” In other words, in order to measure the shape of the focus ring 5, the amounts of projection of the probes 53 with respect to the facing portion 52a are measured. The amounts of projection of the probes 53 are measured by, e.g., a predetermined measurement device. The amounts of projection of the probes 53 may be electrically measured by a displacement meter or the like. The thickness of the focus ring 5 at each of the different radial positions for each of multiple locations in the circumferential direction of the focus ring 5 is calculated by subtracting the amounts of projection of the corresponding probe 53 from the reference thickness “tᵣ.”

The misalignment calculation unit 114 acquires the thicknesses of the focus ring 5 at different radial positions of the focus ring 5 that are calculated from the reference thickness “tᵣ” used for the measuring the shape of the focus ring 5. Then, the misalignment calculation unit 114 specifies the characteristic position of the focus ring for each of the multiple locations in circumferential direction of the focus ring 5 based on the thicknesses of the focus ring 5 measured at the different radial positions of the focus ring 5. Then, the misalignment calculation unit 114 calculates the misalignment amount between the center of the circle passing through the specified characteristic positions of the focus ring 5 and the center of the mounting surface 6c. This misalignment amount is calculated, e.g., in the same manner as that described with reference to FIG. 10. Accordingly, in the plasma processing apparatus 10, the misalignment of the focus ring 5 due to the consumption can be measured highly accurately and simply by using one jig 52 mounted on the mounting surface 6c.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. A plasma processing apparatus comprising:
a mounting table having a first mounting surface on which a plurality of jigs are mounted sequentially one by one and a second mounting surface on which a ring member disposed to surround a target object is mounted, the jigs being used for measuring a shape of the ring member and respectively having facing portions facing an upper surface of the ring member, wherein respective positions of the facing portions of the jigs in a radial direction of the ring member are different from one another;
one or more elevating mechanisms disposed at multiple locations in a circumferential direction of the ring member and configured to lift or lower the ring member with respect to the second mounting surface;
an acquisition unit configured to acquire, when each of the jigs is mounted on the mounting surface, gap information indicating a gap dimension between the second mounting surface and the facing portion of the corresponding jig mounted on the first mounting surface;
a measurement unit configured to measure a lifted distance of the ring member from the second mounting surface at each of the multiple locations in the circumferential direction of the ring member when the upper surface of the ring member is in contact with the facing portion of the corresponding jig by lifting the ring member using the elevating mechanisms in a state where the corresponding jig is mounted on the first mounting surface;
a thickness calculation unit configured to calculate, for each of the multiple locations in the circumferential direction of the ring member, a thickness of the ring member at each of different radial positions of the ring member that correspond to the positions of the facing portions of the jigs based on the gap dimension indicated by the acquired gap information and the measured lifted distance of the ring member; and
a misalignment calculation unit configured to specify a characteristic position that is used to characterize the shape of the ring member for each of the multiple locations in the circumferential direction of the ring member based on the calculated thickness of the ring member and calculate a misalignment amount between a center of a circle passing through the characteristic positions and a center of the first mounting surface.

2. The plasma processing apparatus of claim 1, further comprising:
a misalignment correction unit configured to correct a misalignment of the ring member based on the calculated misalignment amount.

3. The plasma processing apparatus of claim 1, wherein the gap dimension is determined in advance based on a distance between the second mounting surface and the first mounting surface and a distance between the first mounting surface and the facing portion of each of the jigs that is mounted on the first mounting surface.

4. The plasma processing apparatus of claim 1, wherein the mounting table includes an electrostatic chuck configured to attract and hold each of the jigs that are mounted sequentially one by one on the first mounting surface, and
the ring member is lifted by using the elevating mechanisms in a state where the corresponding jig mounted on the first mounting surface is attracted and held by the electrostatic chuck.

5. The plasma processing apparatus of claim 2, wherein the mounting table includes an electrostatic chuck configured to attract and hold each of the jigs that are mounted sequentially one by one on the first mounting surface, and
the ring member is lifted by using the elevating mechanisms in a state where the corresponding jig mounted on the first mounting surface is attracted and held by the electrostatic chuck.

6. The plasma processing apparatus of claim 3, wherein the mounting table includes an electrostatic chuck configured to attract and hold each of the jigs that are mounted sequentially one by one on the first mounting surface, and
the ring member is lifted by using the elevating mechanisms in a state where the corresponding jig mounted on the first mounting surface is attracted and held by the electrostatic chuck.

7. A plasma processing apparatus comprising:
a mounting table having a first mounting surface on which a jig is mounted and a second mounting surface on which a ring member disposed to surround a target object is mounted, the jig being used for measuring a shape of the ring member and having a facing portion facing an upper surface of the ring member, wherein the facing portion is provided with a plurality of vertically movable probes arranged along a radial direction of the ring member;
one or more elevating mechanisms disposed at multiple locations in a circumferential direction of the ring member and configured to lift or lower the ring member with respect to the second mounting surface;
an acquisition unit configured to acquire gap information indicating a gap dimension between the second mounting surface and the facing portion of the jig mounted on the first mounting surface;
a measurement unit configured to measure a lifted distance of the ring member from the second mounting surface at each of the multiple locations in the circumferential direction of the ring member when the upper surface of the ring member is in contact with the facing portion of the jig by lifting the ring member using the elevating mechanisms and pushing upward the probes by using the ring member that is being lifted in a state where the jig is mounted on the first mounting surface;
a thickness calculation unit configured to calculate a reference thickness of the ring member, which is used for measuring the shape of the ring member, for each of the multiple locations in the circumferential direction of the ring member based on the gap dimension indicated by the acquired gap information and the measured lifted distance of the ring member; and
a misalignment calculation unit configured to specify a characteristic position that is used to characterize the shape of the ring member for each of the multiple locations in the circumferential direction of the ring member based on the thicknesses of the ring member at different radial positions of the ring member which are calculated from the reference thickness and to calculate a misalignment amount between a center of a circle passing through the characteristic positions and a center of the first mounting surface,
wherein in order to measure the shape of the ring member, amounts of projection of the probes with respect to the facing portion are measured, and the thicknesses of the ring member at the different radial positions of the ring member are respectively calculated for each of the multiple locations in the circumferential direction of the ring member by subtracting the amounts of projection of the probes from the reference thickness.

8. A method for measuring misalignment of a ring member, the method comprising:
mounting a plurality of jigs sequentially one by one on a first mounting surface of a mounting table, wherein the mounting table has the first mounting surface and a second mounting surface on which a ring member disposed to surround a target object is mounted, the jigs are used for measuring a shape of the ring member and respectively have facing portions facing an upper surface of the ring member, and respective positions of the facing portions of the jigs in a radial direction of the ring member are different from one another;
acquiring, when each of the jigs is mounted on the mounting surface, gap information indicating a gap dimension between the second mounting surface and the facing portion of the corresponding jig mounted on the first mounting surface;
measuring a lifted distance of the ring member from the second mounting surface at each of multiple locations in a circumferential direction of the ring member when the upper surface of the ring member is in contact with the facing portion of the corresponding jig by lifting the ring member using elevating mechanisms, which are respectively arranged at the multiple locations in the circumferential direction of the ring member and configured to lift or lower the ring member with respect to the second mounting surface, in a state where the corresponding jig is mounted on the first mounting surface;
calculating, for each of the multiple locations in the circumferential direction of the ring member, a thickness of the ring member at each of different radial positions of the ring member that correspond to the positions of the facing portions of the jigs based on the gap dimension indicated by the acquired gap information and the measured lifted distance of the ring member; and
specifying a characteristic position that is used to characterize the shape of the ring member for each of the multiple locations in the circumferential direction of the ring member based on the calculated thickness of the ring member and calculating a misalignment amount between a center of a circle passing through the characteristic positions and a center of the first mounting surface.
